(19) United States
(12) Patent Application Publication
(10) Pub. No.: US 2026/0211458 A1
(43) Pub. Date: Jul. 23, 2026

(54) Flexible Display Trim

(71) Applicant: Apple Inc., Cupertino, CA (US)

(72) Inventors: Adam T Garelli, Morgan Hill, CA (US); Robert Y Cao, San Francisco, CA (US); Keith J Hendren, Santa Cruz, CA (US); Ben Hightower, San Jose, CA (US); Evan Paul Lee, Austin, TX (US); Wei Lv, San Jose, CA (US)

(21) Appl. No.: 19/396,135

(22) Filed: Nov. 20, 2025

Related U.S. Application Data
(60) Provisional application No. 63/746,730, filed on Jan. 17, 2025.

(51) Int. Cl. G06F 1/16

(52) U.S. Cl. CPC G06F 1/1656; G06F 1/1616; G06F 1/1652

(57) ABSTRACT

An electronic device may include a flexible display that folds along an axis. A display trim may wrap around a perimeter of the flexible display. The display trim may include a first material that is segmented into a first set of rigid elements on a first side of the display and a second set of rigid elements on a second opposing side of the display. The rigid elements may be U-shaped metal structures that are separated from one another by gaps. The U-shaped metal structures may be configured to receive an edge of the flexible display. The gaps may have non-uniform spacing to provide different amounts of flexibility in different portions of the display trim. The display trim may include a second material that has a lower elastic modulus than the first material and that fills the gaps between the rigid elements.

This application claims the benefit of U.S. provisional patent application No. 63/746,730, filed Jan. 17, 2025, which is hereby incorporated by reference herein in its entirety.

### FIELD

This relates generally to electronic devices and, more particularly, to electronic devices with displays.

### BACKGROUND

Electronic devices often have displays. Portability may be a concern for some devices, which tends to limit available real estate for displays.

### SUMMARY

An electronic device may be provided with a foldable housing that allows the device to fold and unfold about a bend axis. A flexible display may be mounted in the foldable housing. The flexible display may have an array of pixels forming a display panel. The display panel may be configured to bend along the bend axis as the device is folded.

A display trim may wrap around a perimeter of the flexible display. The display trim may have flexible regions that are aligned with the bend axis so that the display trim can flex when the flexible display is folded. The display trim may include a first material that is segmented into a first set of rigid elements on a first side of the display and a second set of rigid elements on a second opposing side of the display. The rigid elements may be U-shaped metal structures or other segmented rigid elements that are separated from one another by gaps. The U-shaped metal structures may be configured to receive an edge of the flexible display. The gaps may have non-uniform spacing to provide different amounts of flexibility in different portions of the display trim.

The display trim may include a second material that has a lower elastic modulus than the first material and that fills the gaps between the rigid elements. The first material may extend continuously along the non-bending regions of the display.

The first material that forms the segmented rigid elements may only be present along the bending region of the display or may also extend around the non-bending regions of the display. If desired, the thickness of the first material may increase at further distances from the bend axis to increase rigidity of the display trim in the non-bending regions.

### BRIEF DESCRIPTION OF THE DRAWINGS

FIG. 1 is a schematic diagram of an illustrative electronic device in accordance with some embodiments.

FIG. 2 is a perspective view of an illustrative electronic device with a display surrounded by a display trim in accordance with some embodiments.

FIG. 3 is a side view of an illustrative electronic device in accordance with some embodiments.

FIG. 4 is a perspective view of an illustrative display trim having a foldable region with first and second sets of segmented rigid members on opposing sides of a flexible display in accordance with some embodiments.

FIG. 5 is a perspective view of an illustrative display trim having a first material that forms first and second sets of segmented rigid members in a bending region and that has continuous portions in non-bending regions in accordance with some embodiments.

FIG. 6 is a perspective view of an illustrative display trim having a first material that forms first and second sets of segmented rigid members in a bending region and that has continuous portions with increased thickness in non-bending regions in accordance with some embodiments.

FIG. 7 is a perspective view of an illustrative electronic device having a display trim that includes a set of unconnected U-shaped elements in a foldable region in accordance with some embodiments.

FIG. 8 is a perspective view of an illustrative electronic device having a display trim that includes a set of connected U-shaped elements in a foldable region in accordance with some embodiments.

### DETAILED DESCRIPTION

Electronic devices may be provided with displays. Displays may be used for displaying images for users. Displays may be formed from arrays of light-emitting diode pixels or other pixels. For example, a device may have an organic light-emitting diode display or a display formed from an array of micro-light-emitting diodes (e.g., diodes formed from crystalline semiconductor dies).

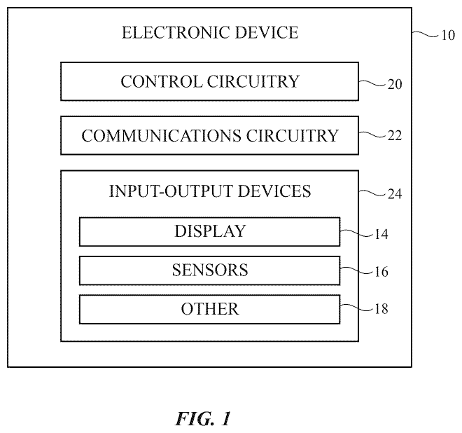

A schematic diagram of an illustrative electronic device having a display is shown in FIG. 1. Device 10 may be a cellular telephone, tablet computer, laptop computer, wristwatch device or other wearable device, a television, a stand-alone computer display or other monitor, a computer display with an embedded computer (e.g., a desktop computer), a system embedded in a vehicle, kiosk, or other embedded electronic device, a media player, or other electronic equipment. Configurations in which device 10 is a cellular telephone, tablet computer, or other portable electronic device may sometimes be described herein as an example. This is illustrative. Device 10 may, in general, be any suitable electronic device with a display.

Device 10 may include control circuitry 20. Control circuitry 20 may include storage and processing circuitry for supporting the operation of device 10. The storage and processing circuitry may include storage such as nonvolatile memory (e.g., flash memory or other electrically-programmable-read-only memory configured to form a solid state drive), volatile memory (e.g., static or dynamic random-access-memory), etc. Processing circuitry in control circuitry 20 may be used to gather input from sensors and other input devices and may be used to control output devices. The processing circuitry may be based on one or more microprocessors, microcontrollers, digital signal processors, baseband processors and other wireless communications circuits, power management units, audio chips, application specific integrated circuits, etc. During operation, control circuitry 20 may use a display and other output devices in providing a user with visual output and other output.

To support communications between device 10 and external equipment, control circuitry 20 may communicate using communications circuitry 22. Circuitry 22 may include antennas, radio-frequency transceiver circuitry (wireless transceiver circuitry), and other wireless communications circuitry and/or wired communications circuitry. Circuitry 22, which may sometimes be referred to as control circuitry and/or control and communications circuitry, may support bidirectional wireless communications between device 10 and external equipment over a wireless link (e.g., circuitry 22 may include radio-frequency transceiver circuitry such as wireless local area network transceiver circuitry configured to support communications over a wireless local area network link, near-field communications transceiver circuitry configured to support communications over a near-field communications link, cellular telephone transceiver circuitry configured to support communications over a cellular telephone link, or transceiver circuitry configured to support communications over any other suitable wired or wireless communications link). Wireless communications may, for example, be supported over a Bluetooth® link, a WiFi® link, a wireless link operating at a frequency between 6 GHz and 300 GHz, a 60 GHz link, or other millimeter wave link, cellular telephone link, wireless local area network link, personal area network communications link, or other wireless communications link. Device 10 may, if desired, include power circuits for transmitting and/or receiving wired and/or wireless power and may include batteries or other energy storage devices. For example, device 10 may include a coil and rectifier to receive wireless power that is provided to circuitry in device 10.

Device 10 may include input-output devices such as devices 24. Input-output devices 24 may be used in gathering user input, in gathering information on the environment surrounding the user, and/or in providing a user with output. Devices 24 may include one or more displays such as display 14. Display 14 may be an organic light-emitting diode display, a liquid crystal display, an electrophoretic display, an electrowetting display, a plasma display, a microelectromechanical systems display, a display having a pixel array formed from crystalline semiconductor light-emitting diode dies (sometimes referred to as microLEDs), and/or other display. Configurations in which display 14 is an organic light-emitting diode display or microLED display are sometimes described herein as an example.

Display 14 may have an array of pixels configured to display images for a user. The pixels may be formed as part of a display panel that is bendable. This allows device 10 to be folded and unfolded about a bend axis. For example, a flexible (bendable) display in device 10 may be folded so that device 10 may be placed in a compact shape for storage and may be unfolded when it is desired to view images on the display.

Sensors 16 in input-output devices 24 may include force sensors (e.g., strain gauges, capacitive force sensors, resistive force sensors, etc.), audio sensors such as microphones, touch and/or proximity sensors such as capacitive sensors (e.g., a two-dimensional capacitive touch sensor integrated into display 14, a two-dimensional capacitive touch sensor overlapping display 14, and/or a touch sensor that forms a button, trackpad, or other input device not associated with a display), and other sensors. If desired, sensors 16 may include optical sensors such as optical sensors that emit and detect light, ultrasonic sensors, optical touch sensors, optical proximity sensors, and/or other touch sensors and/or proximity sensors, monochromatic and color ambient light sensors, image sensors, fingerprint sensors, temperature sensors, sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices that capture three-dimensional images), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 16 and/or other input-output devices to gather user input. For example, buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.

If desired, electronic device 10 may include additional components (see, e.g., other devices 18 in input-output devices 24). The additional components may include haptic output devices, audio output devices such as speakers, light-emitting diodes for status indicators, light sources such as light-emitting diodes that illuminate portions of a housing and/or display structure, other optical output devices, and/or other circuitry for gathering input and/or providing output. Device 10 may also include a battery or other energy storage device, connector ports for supporting wired communication with ancillary equipment and for receiving wired power, and other circuitry.

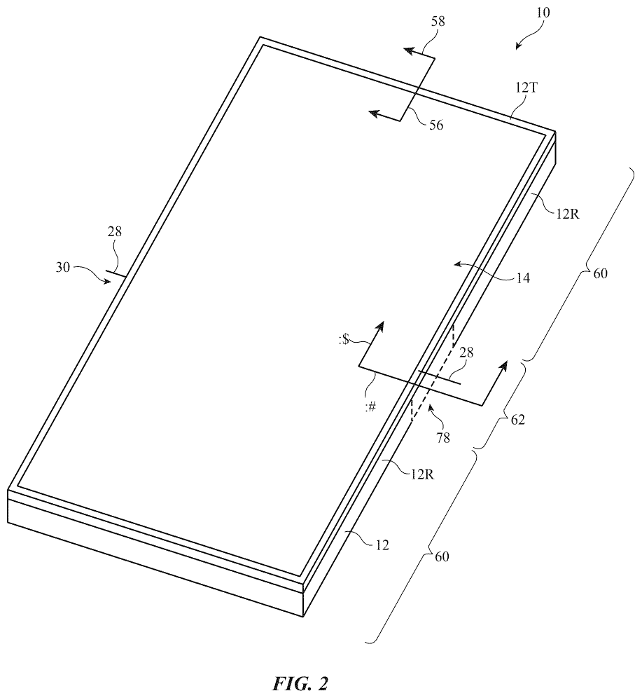

FIG. 2 is a perspective view of electronic device 10 in an illustrative configuration in which device 10 is a portable electronic device such as a cellular telephone or tablet computer. As shown in FIG. 2, device 10 may have a display such as display 14. Display 14 may cover some or all of the front face of device 10. Touch sensor circuitry such as two-dimensional capacitive touch sensor circuitry may be incorporated into display 14.

Display 14 may be mounted in housing 12. Housing 12 may form front and rear housing walls, sidewall structures, and/or internal supporting structures (e.g., a frame, an optional midplate member, etc.) for device 10. Glass structures, transparent polymer structures, and/or other transparent structures that cover display 14 and other portions of device 10 may provide structural support for device 10 and may sometimes be referred to as housing structures. For example, a transparent housing portion such as a glass or polymer housing structure that covers and protects a pixel array in display 14 may serve as a display cover layer for the pixel array while also serving as a housing wall on the front face of device 10. In configurations in which a display cover layer is formed from glass, the display cover layer may sometimes be referred to as a display cover glass or display cover glass layer. The portions of housing 12 on the sidewalls and rear wall of device 10 may be formed from glass or other transparent structures and/or opaque structures. Sidewalls and rear wall structures may be formed as extensions to the front portion of housing 12 (e.g., as integral portions of the display cover layer) and/or may include separate housing wall structures.

Device 10 may be a foldable electronic device that folds along one or more bend axes such as bend axis 28. In the example of FIG. 2, device 10 includes first and second portions 60 joined by bendable portion 62. Portions 60 of device 10 (e.g., portions 60 of display 14 and housing 12, sometimes referred to as the non-bending regions of device 10) may rotate relative to one another about axis 28. As one portion 60 rotates relative to another portion 60 (e.g., during folding and unfolding of device 10), bendable portion 62 of display 14 may bend and flex (e.g., while portions 60 remain flat).

Housing 12 may have flexible structures (e.g., bendable housing wall structures) and/or hinge structures such as hinge 30. Hinge 30 may have a hinge axis aligned with device bend axis 28. Hinge 30 and/or flexible housing structures that overlap bend axis 28 may allow housing 12 to bend about bend axis 28. For example, portion 60 of housing 12 may be located on one side of bend axis 28 and another portion 60 of housing 12 may be located on the opposing side of bend axis 28. Portions 60 of housing 12 may be coupled by hinge 30 for rotational motion about axis 28.

Housing 12 may include rear housing wall 12R and display trim 12T. Rear housing wall 12R may form a rear face of device 10. If desired, rear housing wall 12R may extend continuously across bendable region 62 of device 10, or rear housing wall 12R may have a gap in region 62 such as gap 78 that overlaps and extends parallel to bend axis 28.

Display trim 12T may extend around the periphery of display 14 and may be used to seal display 14 to housing 12. If desired, display trim 12T may form a continuous loop without breaks around display 14. To accommodate bending in region 62 while providing sufficient display protection, display trim 12T may be formed from one or more different types of materials. For example, in an illustrative configuration, display trim 12T may include first and second materials such as a stiff material (e.g., metal, rigid polymers, fiber composite materials, etc.) and a flexible material (e.g., silicone or other flexible polymer). The stiff material may form segmented rigid elements in bend region 62 and may have continuous, thicker portions in non-bending regions 60. The rigid elements in bend region 62 may have sufficient strength to protect the edges of display 14 in bend region 62, while the presence of gaps between the rigid elements in region 62 allows display trim 12T to bend and flex as device 10 is folded and unfolded. The soft material may provide trim 12T with a uniform exterior appearance around the periphery of display 14.

Rigid materials in display trim 12T may include rigid polymers (e.g., polycarbonate, etc.), fiber-reinforced materials (e.g., carbon fiber, fiberglass, etc.), composite materials, metal (e.g., steel, aluminum, etc.), and/or other suitable materials. Soft materials in display trim 12T may include soft polymers (e.g., elastomeric materials, polyurethane, silicone, etc.), fabric, and/or other suitable materials. Because trim 12T extends continuously around display 14 and is able to follow (e.g., conform to) the curvature of display 14 during folding and unfolding, display 14 may be sealed to display trim 12T using a seal that forms a continuous loop without breaks around the display (or, if desired, trim 12T may be molded directly to display 14 without using a separate seal). The seal may be located between display 14 and trim 12T and/or may be formed between trim 12T and other portions of housing 12 (e.g., an outer housing sidewall and/or a rear wall of housing 12).

As housing 12 is bent about bend axis 28, the flexibility of display 14 allows display 14 to bend about axis 28. In an illustrative configuration, housing 12 and display 14 may bend by 180°. This allows display 14 to be folded back on itself (with first and second outwardly facing portions of display 14 facing each other). The ability to place device 10 in a folded configuration in this way may help make device 10 compact so that device 10 can be stored efficiently. When it is desired to view images on display 14, device 10 may be unfolded about axis 28 to place device 10 in the unfolded configuration of FIG. 2. This allows display 14 to lie flat and allows a user to view flat images on display 14. The ability to fold display 14 onto itself allows device 10 to exhibit an inwardly folding behavior. Display 14 may be sufficiently flexible to allow device 10 to be folded outwardly and/or inwardly.

Device 10 of FIG. 2 has a rectangular outline (rectangular periphery) with four corners. As shown in FIG. 2, a first pair of parallel edges (e.g., the left and right edges of device 10 in the example of FIG. 2) may be longer than a second pair of parallel edges (e.g., the upper and lower edges of device 10 of FIG. 2) that are oriented at right angles to the first pair of parallel edges. In this type of configuration, housing 12 is elongated along a longitudinal axis that is perpendicular to bend axis 28. Housing 12 may have other shapes, if desired (e.g., shapes in which housing 12 has a longitudinal axis that extends parallel to bend axis 28). With an arrangement of the type shown in FIG. 2, the length of device 10 along its longitudinal axis may be reduced by folding device 10 about axis 28.

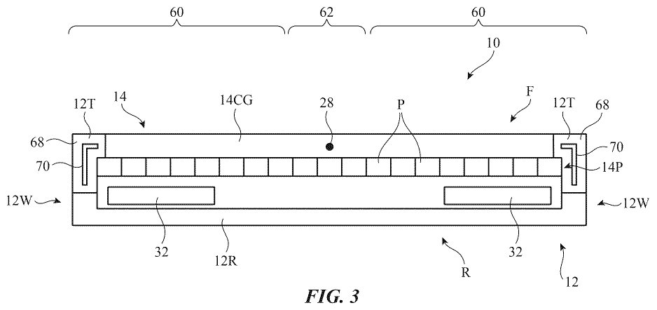

FIG. 3 is a cross-sectional side view of an illustrative foldable electronic device. Device 10 of FIG. 3 may bend about bend axis 28. Bend axis 28 may be aligned with display cover layer 14CG or other structures in device 10. For example, bend axis 28 may pass through a portion of display cover layer 14CG or may be located above or below layer 14CG.

As shown in FIG. 3, display 14 includes an array of pixels P forming display panel 14P under an inwardly facing surface of display cover layer 14CG. Display panel 14P may be, for example, a flexible organic light-emitting diode display or a microLED display in which light-emitting pixels are formed on a flexible substrate layer (e.g., a flexible layer of polyimide or a sheet of other flexible polymer). Flexible support layer(s) for display 14 may also be formed from flexible glass, flexible metal, and/or other flexible structures.

Display cover layer 14CG may be formed from polymer, glass, crystalline materials such as sapphire, other materials, and/or combinations of these materials. To enhance flexibility, a portion of layer 14CG that overlaps bend axis 28 may be locally thinned (e.g., this portion may be thinned relative to portions of layer 14CG that do not overlap bend axis 28). The thickness of layer 14CG (e.g., the non-thinned portions of layer 14CG) may be 50-200 microns, 70-150 microns, 100-200 microns, 100-600 microns, at least 100 microns, at least 200 microns, less than 600 microns, less than 400 microns, less than 250 microns, less than 150 microns, less than 100 microns, at least 50 microns, or other suitable thickness.

In the example of FIG. 3, housing 12 has a portion 12R on rear face R that forms a rear housing wall, has side portions forming sidewalls 12W, and has trim portions forming display trim 12T (e.g., a frame around display 14). If desired, some or all of rear housing wall 12R, sidewalls 12W, and display trim 12T may be formed from the same material and/or a unitary structure. For example, display trim 12T may also from sidewalls 12W, if desired. The rear housing wall 12R of housing 12 may form a support layer for components in device 10. Housing 12 may also have one or more interior supporting layers (e.g., frame structures such as an optional midplate, etc.). These interior supporting layers and the rear housing wall may have first and second portions that are coupled to opposing sides of a hinge that is aligned with bend axis 28 (see, e.g., hinge 30 of FIG. 2) or may be sufficiently flexible to bend around bend axis 28.

Electrical components 32 may be mounted in the interior of device 10 (e.g., between display 14 and the rear of housing 12. Components 32 may include circuitry of the type shown in FIG. 1 (e.g., control circuitry 20, communications circuitry 22, input-output devices 24, batteries, etc.). Display 14 may be mounted on front face F of device 10. When device 10 is folded about axis 28, display cover layer 14CG, display panel 14P, and the other structures of device 10 that overlap bend axis 28 may flex and bend to accommodate folding.

Trim 12T may extend partially or completely around the periphery of device 10. If desired, trim 12T may have a different construction in non-bending regions 60 of display 14 than in bending region 62 of display 14. In particular, non-bending regions 60 of display 14 may include first material 70 (e.g., a rigid material having a first elastic modulus) and second material 68 (e.g., a soft material having a second elastic modulus that is lower than the first elastic modulus). Material 70 may be formed from metal, fiber composite, rigid polymer, and/or other suitable materials. Material 68 may be an overmolded polymer such as silicone or other suitable polymer. In bending region 62, material 70 may be segmented and/or may have a reduced thickness to accommodate bending. Material 70 may extend around the entire perimeter of display 14 (e.g., in a continuous or broken loop), or material 70 may only be located in bend region 62. Material 70 may have continuous, solid portions in non-bending regions 60 and may have discontinuous, segmented portions in bending region 62. For example, in bending region 62, material 70 may include a set of distinct, unconnected rigid elements (e.g., pillar or post-shaped elements, U-shaped elements, etc.), or material 70 may be formed from a unitary rigid structure with cut-outs (e.g., gaps) that form segmented rigid elements (e.g., pillar or post-shaped elements, U-shaped elements, etc.). Material 70 may provide increased strength and display protection while still allowing display 14 to bend.

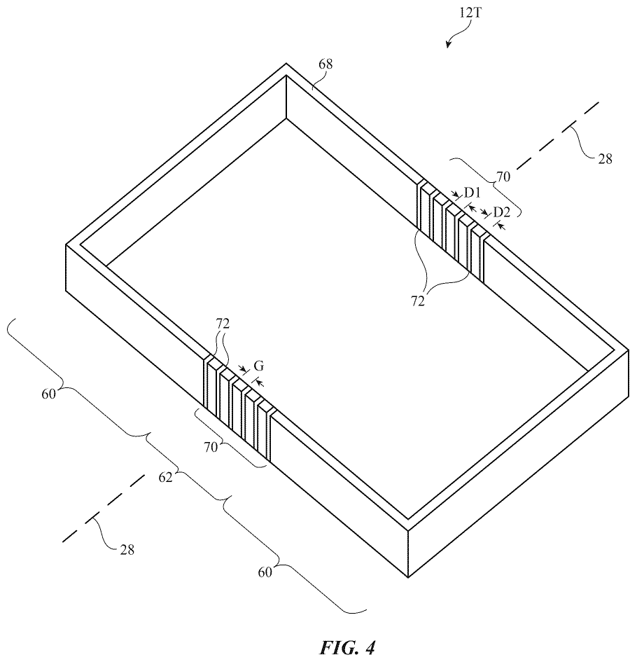

FIG. 4 is a perspective view of an illustrative display trim 12T. As shown in FIG. 4, display trim 12T may include first material 70 and second material 68. In the example of FIG. 4, first material 70 is located only in bending region 62 and is absent from non-bending regions 60. In non-bending regions 60, trim 12T may be formed entirely of second material 68. In bending region 62, trim 12T may be formed from first material 70 and second material 68. First material 70 is segmented into multiple individual rigid elements 72. Rigid elements 72 may be pillar or post-shaped elements, U-shaped elements, C-shaped elements, and/or elements of other suitable shapes. Rigid elements 72 may be formed from metal, fiber composite material, polymer, or other suitable materials. Rigid elements 72 may be separate and distinct elements that are disconnected from one another, if desired. Trim 12T may include a first set of segmented rigid elements 72 on a first side of display panel 14P and a second set of segmented rigid elements 72 on a second opposing side of display panel 14P.

As shown in FIG. 4, rigid elements 72 may be separated by gaps G. Second material 68 may fill gaps G in bending region 62 and may have continuous segments that form trim 12T in non-bending regions 60. Gaps G may have uniform spacing across elements 72, or gaps G may have different spacing to accommodate different bending shapes. To increase flexibility of trim 12T around bend axis 28, gaps G may be larger at closer distances to axis 28 and may be smaller at further distances away from axis 28. For example, gaps G that are aligned or overlapping with bend axis 28 may have dimension D1, whereas gaps G that are offset from bend axis 28 may have dimension D2 (e.g., a value smaller than D1). The presence of larger gaps G between elements 72 that are aligned with axis 28 may facilitate bending, whereas smaller gaps G may help increase the rigidity of trim 12T as region 62 approaches region 60.

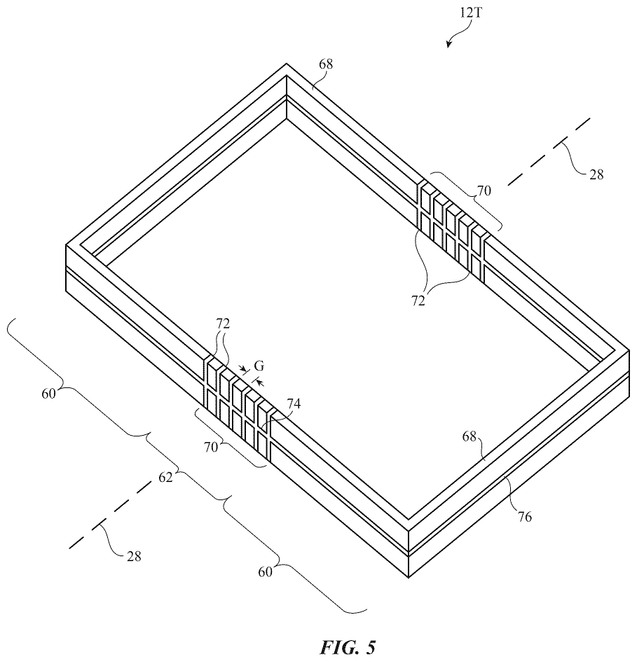

In the example of FIG. 5, first material 70 is located both in bending region 62 and non-bending regions 60. In non-bending regions 60, trim 12T may be formed of first material 70 and second material 68. If desired, first material 70 may be embedded in second material 68. For example, first material 70 may be formed from a rigid metal frame and second material 68 may be overmolded onto the metal frame. First material 70 may be entirely covered and hidden from view by second material 68, if desired. In other arrangements, first material 70 may be exposed on the exterior of trim 12T.

In bending region 62, trim 12T may be formed from first material 70 and second material 68. First material 70 is segmented into multiple individual rigid elements 72. Rigid elements 72 may be pillar or post-shaped elements, U-shaped elements, C-shaped elements, and/or elements of other suitable shapes. Rigid elements 72 may be formed from metal, fiber composite material, polymer, and/or other suitable materials. Rigid elements 72 may be connected to one another by segment 74 (e.g., metal, fiber composite, polymer, etc.). By connecting rigid elements 72 with segment 74 on each side of display 14, material 70 may form a unitary frame member that extends around the entire perimeter of display 14 (e.g., one piece of metal or other rigid material that is segmented in bending region 62 and solid in non-bending regions 60). Trim 12T may include a first set of segmented rigid elements 72 on a first side of display panel 14P and a second set of segmented rigid elements 72 on a second opposing side of display panel 14P.

Rigid elements 72 may be separated by gaps G. Second material 68 may fill gaps G in bending region 62 and may have continuous segments that form trim 12T in non-bending regions 60. Gaps G may have uniform spacing across elements 72, or gaps G may have different spacing to accommodate different bending shapes. To increase flexibility of trim 12T around bend axis 28, gaps G may be larger at closer distances to axis 28 and smaller at further distances away from axis 28, if desired. The presence of larger gaps G between elements 72 that are aligned with axis 28 may facilitate bending, whereas smaller gaps G may help increase the rigidity of trim 12T as region 62 approaches region 60.

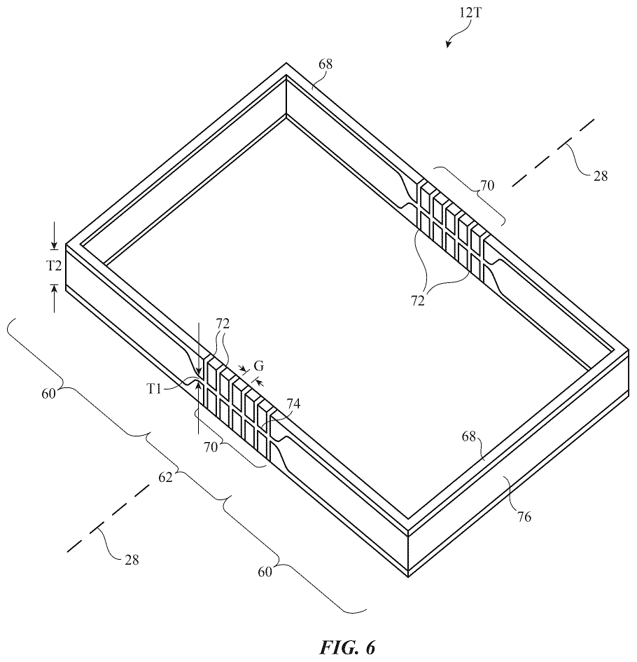

In the example of FIG. 6, first material 70 is located both in bending region 62 and non-bending regions 60, and first material 70 has a tapered thickness to increase flexibility in bending region 62 and increase rigidity in non-bending regions 60. In non-bending regions 60, trim 12T may be formed of first material 70 and second material 68. If desired, first material 70 may be embedded in second material 68. For example, first material 70 may be formed from a rigid metal frame and second material 68 may be overmolded onto the metal frame. First material 70 may be entirely covered and hidden from view by second material 68, if desired. In other arrangements, first material 70 may be exposed on the exterior of trim 12T.

In bending region 62, trim 12T may be formed from first material 70 and second material 68. First material 70 is segmented into multiple individual rigid elements 72. Rigid elements 72 may be pillar or post-shaped elements, U-shaped elements, C-shaped elements, and/or elements of other suitable shapes. Rigid elements 72 may be formed from metal, fiber composite material, polymer, and/or other suitable materials. Rigid elements 72 may be connected to one another by segment 74 (e.g., metal, fiber composite, polymer, etc.). By connecting rigid elements 72 with segment 74 on each side of display 14, material 70 may form a unitary frame member that extends around the entire perimeter of display 14 (e.g., one piece of metal or other rigid material that is segmented in bending region 62 and solid in non-bending regions 60). Trim 12T may include a first set of segmented rigid elements 72 on a first side of display panel 14P and a second set of segmented rigid elements 72 on a second opposing side of display panel 14P.

Rigid elements 72 may be separated by gaps G. Second material 68 may fill gaps G in bending region 62 and may have continuous segments that form trim 12T in non-bending regions 60. Gaps G may have uniform spacing across elements 72, or gaps G may have different spacing to accommodate different bending shapes. To increase flexibility of trim 12T around bend axis 28, gaps G may be larger at closer distances to axis 28 and smaller at further distances away from axis 28, if desired. The presence of larger gaps G between elements 72 that are aligned with axis 28 may facilitate bending, whereas smaller gaps G may help increase the rigidity of trim 12T as region 62 approaches region 60.

As shown in FIG. 6, material 70 may gradually increase in thickness as it extends from bending region 62 to non-bending regions 60. For example, material 70 on the opposing sides of rigid elements 72 may have a first thickness T1 in bending region 62. As material 70 approaches non-bending regions 60, material 70 may increase in thickness to thickness T2 (e.g. a thickness larger than thickness T1). Increasing the thickness of material 70 in non-bending regions 60 may help increase the robustness of display trim 12T in non-bending regions 60.

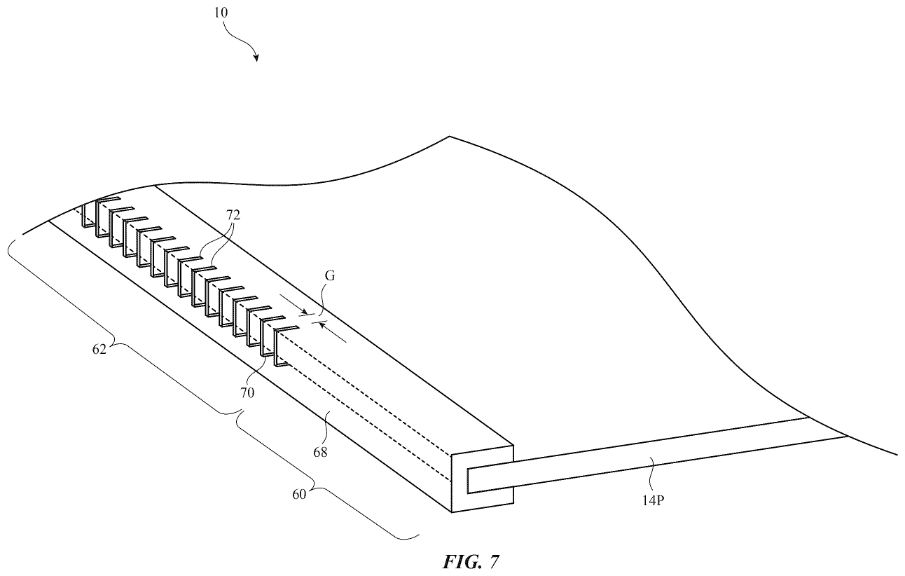

FIG. 7 is a perspective view of device 10 showing an illustrative configuration for display trim 12T (e.g., trim 12T of FIGS. 3, 4, 5, and/or 6). As shown in FIG. 7, trim 12T may include first material 70 and second material 68. First material 70 may be segmented into elements 72 in bending region 60. Trim 12T may include a first set of segmented rigid elements 72 on a first side of display panel 14P and a second set of segmented rigid elements 72 on a second opposing side of display panel 14P. Elements 72 may be U-shaped elements having first and second portions joined by a third portion. If desired, display panel 14P (or one or more layers within display panel 14P) may be received within U-shaped elements 72 and may be sandwiched between the first and second portions of each U-shaped element 72. Material 68 may be overmolded onto rigid elements 72 and may also have a U-shape that receives the edge of display panel 14P, if desired. Material 68 may fill gaps G between rigid elements 72.

If desired, material 70 may only be present in bend region 60 (as in the example of FIG. 4), or material 70 may extend around the entire perimeter of display 14 in a continuous or broken loop (as in the examples of FIGS. 5 and 6).

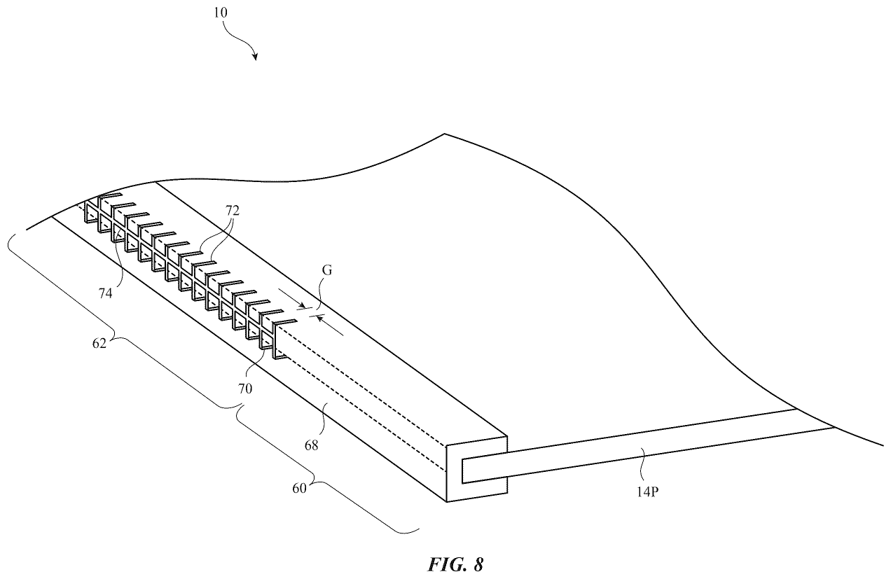

FIG. 8 is a perspective view of device 10 showing an illustrative configuration for display trim 12T (e.g., trim 12T of FIGS. 3, 4, 5, and/or 6). As shown in FIG. 8, trim 12T may include first material 70 and second material 68. First material 70 may be segmented into elements 72 in bending region 60. Trim 12T may include a first set of segmented rigid elements 72 on a first side of display panel 14P and a second set of segmented rigid elements 72 on a second opposing side of display panel 14P. Elements 72 may be U-shaped elements having first and second portions joined by a third portion. If desired, display panel 14P (or one or more layers within display panel 14P) may be received within U-shaped elements 72 and may be sandwiched between the first and second portions of each U-shaped element 72. Material 68 may be overmolded onto rigid elements 72 and may also have a U-shape that receives the edge of display panel 14P, if desired. Material 68 may fill gaps G between rigid elements 72.

Rigid elements 72 may be connected to one another by segment 74 (e.g., metal, fiber composite, polymer, etc.). By connecting rigid elements 72 with segment 74 on each side of display 14, material 70 may form a unitary frame member that extends around the entire perimeter of display 14 (e.g., one piece of metal or other rigid material that is segmented in bending region 62 and solid in non-bending regions 60).

If desired, material 70 may only be present in bend region 60 (as in the example of FIG. 4), or material 70 may extend around the entire perimeter of display 14 in a continuous or broken loop (as in the examples of FIGS. 5 and 6).

Device 10 may be operated in a system that uses personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. An electronic device, comprising:
a flexible display having a bendable region configured to bend along a bend axis; and
a display trim that extends around a perimeter of the flexible display, wherein the display trim comprises:
a first set of segmented rigid elements on a first side of the bendable region; and
a second set of segmented rigid elements on a second side of the bendable region.

2. The electronic device defined in claim 1 wherein the first and second sets of segmented rigid elements comprise U-shaped elements.

3. The electronic device defined in claim 2 wherein the flexible display comprises a display panel having a pixel array and a cover layer that overlaps the display panel.

4. The electronic device defined in claim 3 wherein the U-shaped elements are configured to receive an edge of the display panel.

5. The electronic device defined in claim 2 wherein the U-shaped elements are formed from metal and are separated from one another by gaps.

6. The electronic device defined in claim 5 wherein display trim further comprises a polymer material that fills the gaps.

7. The electronic device defined in claim 6 wherein the polymer material extends around the perimeter of the flexible display.

8. The electronic device defined in claim 1 wherein a spacing between the segmented rigid elements in the first and second sets of segmented rigid elements is non-uniform.

9. The electronic device defined in claim 1 wherein the segmented rigid elements in first set of segmented rigid elements are connected to one another and wherein the segmented rigid elements in the second set of segmented rigid elements are connected to one another.

10. The electronic device defined in claim 1 wherein the display trim further comprises:
a first material that connects the first set of segmented rigid elements to the second set of segmented rigid elements; and
a second material that covers the first material, wherein the second material has a lower elastic modulus than the first material.

11. An electronic device, comprising:
a flexible display having a bending region that bends along a bend axis and that is interposed between first and second non-bending regions of the flexible display; and
a display trim that extends around the flexible display, wherein the display trim comprises:
a first material that is segmented along the bending region of the flexible display; and
a second material that is continuous along the non-bending regions of the flexible display, wherein the second material has a lower elastic modulus than the first material.

12. The electronic device defined in claim 11 wherein the first material comprises metal and the second material comprises polymer that is overmolded onto the metal.

13. The electronic device defined in claim 12 wherein the metal forms U-shaped elements that receive an edge of the flexible display.

14. The electronic device defined in claim 13 wherein the U-shaped elements are separated by gaps in the bending region of the flexible display.

15. The electronic device defined in claim 14 wherein the polymer fills the gaps.

16. An electronic device, comprising:
a foldable display configured to fold along an axis; and
a display trim having a flexible region aligned with the axis, wherein the display trim comprises rigid elements in the flexible region that are separated from one another by gaps.

17. The electronic device defined in claim 16 wherein the rigid elements are formed from a first material that extends around a perimeter of the foldable display, wherein the first material increases in thickness at further distances away from the axis.

18. The electronic device defined in claim 16 wherein the display trim comprises a polymer that fills the gaps.

19. The electronic device defined in claim 16 wherein the gaps have non-uniform spacing.

20. The electronic device defined in claim 16 wherein the rigid elements comprise U-shaped metal structures that are configured to receive an edge of the foldable display.
